(19) United States
(12) Patent Application Publication
(10) Pub. No.: US 2011/0147832 A1
(43) Pub. Date: Jun. 23, 2011

(54) SEMICONDUCTOR DEVICE AND METHOD FOR FABRICATING THE SAME

(75) Inventor: Woong CHOI, Seoul (KR)

(73) Assignee: Hynix Semiconductor Inc., Icheon (KR)

(21) Appl. No.: 12/839,120

(22) Filed: Jul. 19, 2010

(30) Foreign Application Priority Data
Dec. 21, 2009 (KR) 10-2009-0127899

(51) Int. Cl. H01L 29/78; H01L 21/336

(52) U.S. Cl. 257/330; 438/270; 257/E29.262; 257/E21.41

(57) ABSTRACT

A method for fabricating a semiconductor device, the method comprising: forming a mask pattern over a semiconductor substrate including a device isolation film; etching the semiconductor substrate with the mask pattern as a barrier to form a recess having a semi-circular shape; filling a sacrificial material in the semi-circular shaped recess and between the mask pattern; removing the mask pattern; forming a silicon layer in a portion where the mask pattern is removed; removing the sacrificial material to form a gate region; and providing to gate electrode material in the gate region to form a gate pattern thereby enlarging the radius of curvature of the lower portion of the buried gate to improve a DIBL characteristic and enlarging the area of the part connected to a gate junction to improve contact resistance.

### CROSS-REFERENCE TO RELATED APPLICATION

The priority of Korean patent application No. 10-2009-0127899 filed on Dec. 21, 2009, the disclosure of which is hereby incorporated in its entirety by reference, is claimed.

### BACKGROUND OF THE INVENTION

An embodiment of the present invention relates to a semiconductor device and a method for fabricating the same, and more specifically, to a method for forming a buried gate.

Due to a high integration of semiconductor memory devices such as DRAM, a memory cell has been micro-sized. As a result, various efforts to secure a given cell capacitance and improve a cell transistor characteristic in the micro-sized memory cell have been made. As a memory cell has been micro-sized, a smaller-sized cell transistor has been required.

In order to obtain a cell transistor that has no micro-sized problems, a method for controlling an impurity concentration in a diffusion layer has been repeatedly performed. However, as a channel length has been reduced, it is difficult to control the depth of the diffusion layer of the transistor through various thermal treatment processes during the device manufacturing process. Moreover, the effective channel length is decreased and a threshold voltage is reduced, which results in a short channel effect, thereby degrading the operation of the cell transistor.

In order to prevent the degradation, a buried gate transistor including a trench formed on a substrate surface and a transistor gate in the trench has been suggested. Since a gate is formed in the trench to increase a distance between a source and a drain, the buried gate transistor increases the effective channel length, thereby reducing the short channel effect.

FIGS. 1a to 1c are cross-sectional diagrams illustrating a conventional method for fabricating a semiconductor device.

Referring to FIG. 1a, a first hard mask pattern (not shown) that defines a device isolation region is formed on an upper portion of a semiconductor substrate 100. The semiconductor substrate 100 is etched with the first hard mask pattern (not shown) as a mask to form a trench for device isolation. An insulating material is buried in the trench to form a device isolation film 105. A planarizing process is performed to expose the first hard mask pattern (not shown), and the first hard mask pattern (not shown) is removed. When the first hard mask pattern (not shown) is removed, the device isolation film 105 is formed higher than the semiconductor substrate 100. An additional washing process is performed so that the height of the device isolation film 105 may be identical with that of the semiconductor substrate 100.

Referring to FIG. 1b, a second hard mask pattern (not shown) that defines a buried gate region is formed on the upper portion of the semiconductor substrate 100 including the device isolation film 105. The semiconductor substrate 100 is etched with the second hard mask pattern (not shown) as a mask to form a recess 110. As the design rule has been reduced to a micro-size level, the width of the recess 110 has been made smaller. Also, as the aspect ratio of the recess 110 increases, it is difficult to etch the semiconductor substrate 100 vertically. As a result, the recess 110 cannot be vertically etched to have a slope so that the lower portion of the recess 110 is formed in an overturned ‘A’ shape. A gate oxide film 115 is formed on the surface of the semiconductor substrate 100 including the recess 110 by an oxidation process.

Referring to FIG. 1c, a gate electrode material 120 is buried in the lower portion of the recess 110, and a gate insulating film 115 is buried on the upper portion of the gate electrode material 120 in the recess 110, thereby obtaining a buried gate 127.

As mentioned above, when the buried gate 127 is formed, the lower portion of the recess 110 is formed in a V shape so that it is difficult to form the gate insulating film at a uniform thickness. Even though the gate insulating film is formed to have a uniform thickness, an electronic field is concentrated at the sharp bottom of the lower portion of the recess 110, thereby degrading a gate characteristic. Specifically, a Drain Induced Barrier Lowering (DIBL) characteristic is caused, and also a gate off characteristic becomes degraded.

### BRIEF SUMMARY OF THE INVENTION

Various embodiments of the invention are directed to changing the shape of the lower portion of the buried gate to improve a gate characteristic.

According to an embodiment of the present invention, A method for fabricating a semiconductor device, the method comprising: forming a mask pattern over a semiconductor substrate including a device isolation film; etching the semiconductor substrate with the mask pattern as a barrier to form a recess having a semi-circular shape; filling a sacrificial material in the semi-circular shaped recess and between the mask pattern; removing the mask pattern; forming a silicon layer in a portion where the mask pattern is removed; removing the sacrificial material to form a gate region; and providing gate electrode material in the gate region to form a gate pattern.

The device isolation film is formed at a higher level than the top surface of the semiconductor substrate. The width of the top side of the recess is formed to be larger than that between the mask patterns. The width between the mask patterns ranges reduced by 20 to 50% to with respect to the size of a buried gate.

The forming-a-mask-pattern includes: performing a photo-etching process with a buried gate mask to form a pattern; and forming a spacer at sidewalls of the pattern. The forming-a-recess is performed by an isotropic process, wherein the semi-circular shape has a width that is greater than the depth. After forming a recess, further comprising forming a gate insulating film an the surface of the recess.

The sacrificial material includes one selected from the group consisting of a nitride film, an oxide film and a combination thereof. The forming-a-silicon-layer includes depositing silicon in the portion where the mask pattern is removed. The forming-a-silicon-layer is performed by a Selective Epitaxial Growth (SEG) process. The silicon layer is formed to a higher location than that of the sacrificial material.

After forming a silicon layer, further comprising depositing a gate insulating film.

A semiconductor device comprising: a gate region including a recess in a semiconductor substrate and a neck part having a smaller width than that of the recess, the recess having a width and a depth, the width of the recess being greater than the depth of the recess; a gate electrode formed in a lower portion of the gate region; and a gate hard mask disposed on an upper portion of the gate electrode.

Further comprising a gate insulating film disposed below the gate electrode. Further comprising a silicon layer disposed at a side of the neck part of the gate region.

The gate electrode is formed in the recess and a lower portion of the neck part. A semiconductor device comprising: a buried gate pattern formed in a substrate, the buried gate including a lower gate pattern formed in a recess and an upper gate pattern extending from the lower gate pattern, wherein the upper gate pattern has a first width, and the lower gate pattern has a second width larger than the first width.

The substrate comprising: a first substrate formed between the lower gate patterns; and a second substrate extending from the first substrate and formed between the upper gate patterns.

The second substrate is an epitaxial layer of the first substrate. T the recess has a horizontal dimension that is great than a vertical dimension.

### BRIEF DESCRIPTION OF THE DRAWINGS

FIGS. 1a to 1c are cross-sectional diagrams illustrating a conventional method for fabricating a semiconductor device.

FIGS. 2a to 2j are cross-sectional diagrams illustrating a method for fabricating a semiconductor device according to an embodiment of the present invention.

FIG. 3 is a cross-sectional diagram illustrating a semiconductor device according to an embodiment of the present invention.

### DESCRIPTION OF EMBODIMENTS

The present invention will be described in detail with reference to the attached drawings.

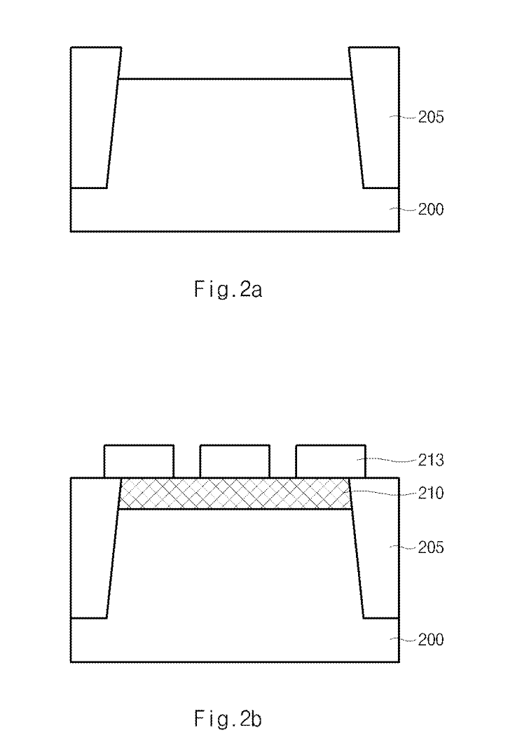

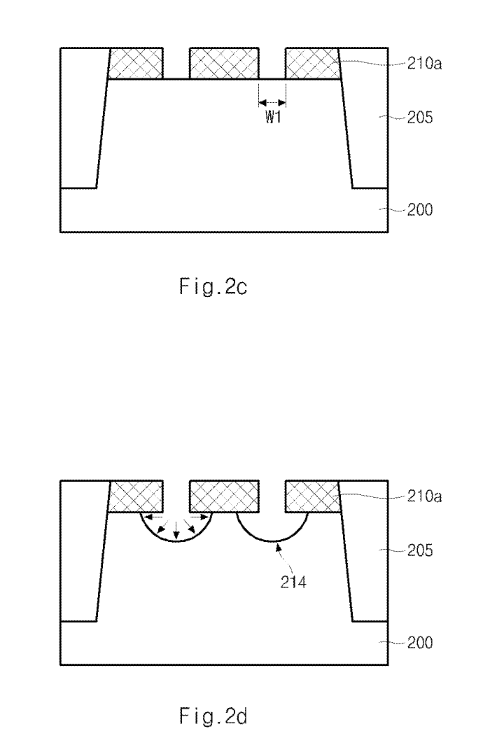

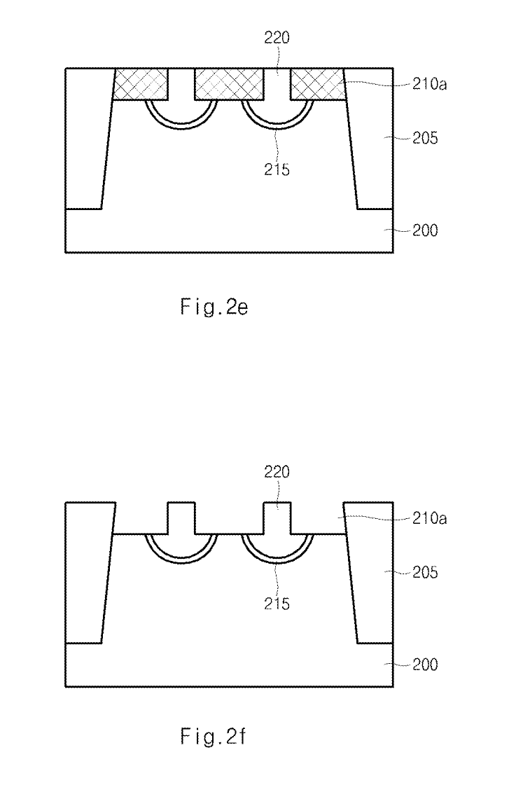

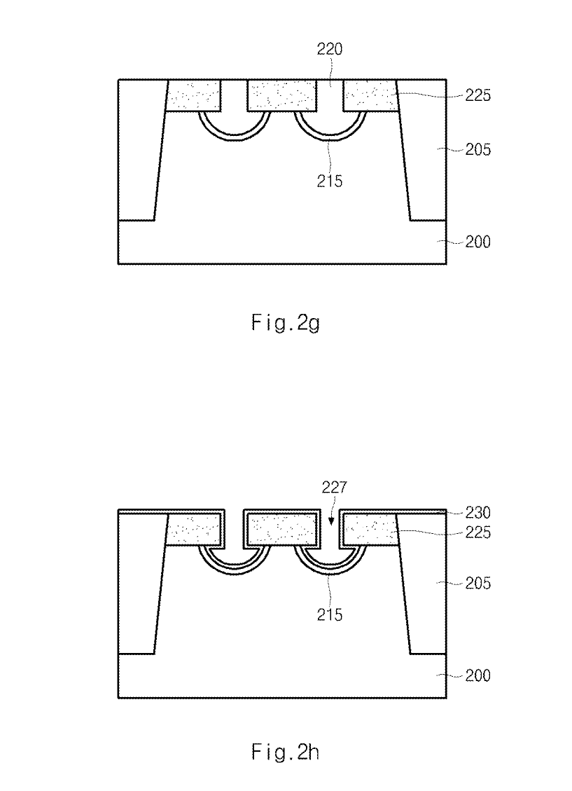

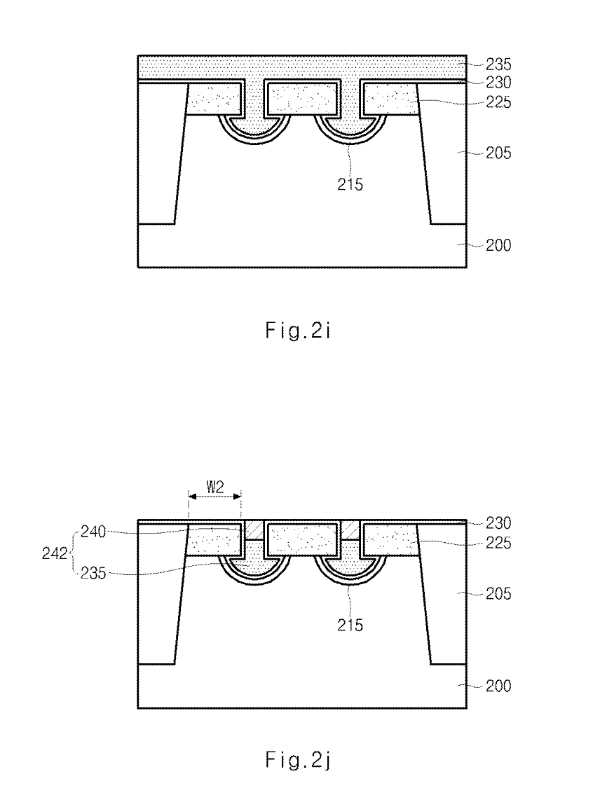

FIGS. 2a to 2j are cross-sectional diagrams illustrating a method for fabricating a semiconductor device according to an embodiment of the present invention.

Referring to FIG. 2a, a first hard mask pattern (not shown) that defines a device isolation region is formed on an upper portion of a semiconductor substrate 200. The semiconductor substrate 200 is etched with the first hard mask pattern (not shown) as a mask to form a trench for device isolation.

After an insulating material is formed on the upper portion of the semiconductor substrate 200 including the trench, a planarizing process is performed to form a device isolation film 205. The insulating film includes an oxide film. The first hard mask pattern (not shown) is removed. Since the device isolation film 205 is formed to substantially the same height as the first hard mask pattern (not shown), the device isolation film 205 is formed to be higher than the top side of the semiconductor substrate 200.

Referring to FIG. 2b, a hard mask material is deposited on the upper portion of the semiconductor substrate 200, and a planarizing process is performed to expose the top side of the device isolation film 205, thereby forming a second hard mask 210. For the second hard mask 210, the first hard mask pattern (not shown) used to form the device isolation film 205 in the process shown in FIG. 2a can be used without being removed.

A photoresist pattern 213 that defines a buried gate region is formed on the upper portion of the second hard mask layer 210.

Referring to FIG. 2c, the second hard mask layer 210 is etched with the photoresist pattern 213 as a mask to form a second hard mask pattern 210a that exposes the semiconductor substrate 200. The photoresist pattern 213 is removed. The width W1 between the second hard mask patterns 210a has a width reduced by 20-50% with respect to the size of a buried gate which will be formed in a subsequent process. Although a fine width is used, an isotropic etching process is performed to increase the width of the bottom surface, thereby obtaining a buried gate that has a large radius of curvature.

A photo etching process is performed with a mask that has a width of a general buried gate to form a mask pattern. A spacer is formed on the sidewalls of the mask pattern so that a mask pattern having a fine width can be formed without using a high resolution photo process.

Referring to FIG. 2d, an isotropic etching process is performed on the semiconductor substrate 200 with the second hard mask pattern 210a as a barrier. When the isotropic etching process using the fine width between the second hard mask pattern 210a, the width of the etched surface increases although the width of the entrance is narrow, thereby forming a recess 214 that has a bottom surface with a large radius of curvature. The recess 214 with a large radius of curvature has the same effective channel length as that of the conventional buried gate, and an increased contact part with a junction secured in a subsequent process.

Referring to FIG. 2e, a first gate insulating film 215 is grown on the surface of the recess 214. The first gate insulating film 215 is formed with a material including an oxide film. Since the recess 214 is formed to have a semi-circular shape with a large radius of curvature, the first gate insulating film 215 having a uniform thickness can be grown by a thermal oxidation process. As used herein, the term “semi-circular shape” refers to a curvature having a relatively large radius so that a distance of the largest segment defined by the curvature is greater than the vertical depth defined by the curvature.

A sacrificial material 220 is formed on the entire surface of the semiconductor substrate 200 including the second hard mask pattern 210a and the recess 214. A planarizing process is performed to expose the top side of the second hard mask pattern 210a. A process for forming a sacrificial material 220 is performed to define a portion with a neck part which is the upper portion of the buried gate when a silicon layer is deposited or grown. The sacrificial material 220 is formed with a material that can be easily removed such as a nitride film, an oxide film and combinations thereof. An oxide film that can be used in the sacrificial material 220 has a faster wet etch speed than that of the oxide film used in the first gate insulating film 215 and the device isolation film 205.

Referring to FIG. 2f, the second hard mask pattern 210a is removed. The first gate insulating film 215 is located in the lower portion of the sacrificial material 220. The sacrificial material 220 has a body layer filling the recess 214 in the substrate 200 and a neck layer extended from the body layer and elevated upward from the top surface of the semiconductor substrate 200.

Referring to FIG. 2g, a silicon layer 225 is formed in a portion where the second hard mask pattern 210a is removed. The silicon layer 225 may be deposited on the upper portion of the semiconductor substrate 200 by a Selective Epitaxial Growth (SEG) process using an exposed semiconductor substrate 200 as a seed.

Referring to FIG. 2h, the sacrificial material 220 is removed to form a buried gate region 227. A second gate insulating film 230 is formed on the surface of the device isolation film 205 and the silicon layer 225 including the gate region 227. A second gate insulating film 230 is formed by the same process for forming the first gate insulating film 215, that is, by a thermal oxidation process. When the first gate insulating film 215 is damaged in the process for removing the sacrificial material 220, the process for forming the second gate insulating film 230 is performed to compensate the damage. The process for forming the second gate insulating film 230 may not be performed.

Referring to FIG. 2i, a gate electrode material 235 is deposited on the resultant surface of the semiconductor substrate 200 including the buried gate region 227. The gate electrode material 235 is formed with a material including tungsten. Referring to FIG. 2j, an etch-back process is performed so that the gate electrode material 235 remains only in the lower portion of the buried gate region 227. The gate electrode material 235 is formed at a lower level than the top surface of the silicon layer 225.

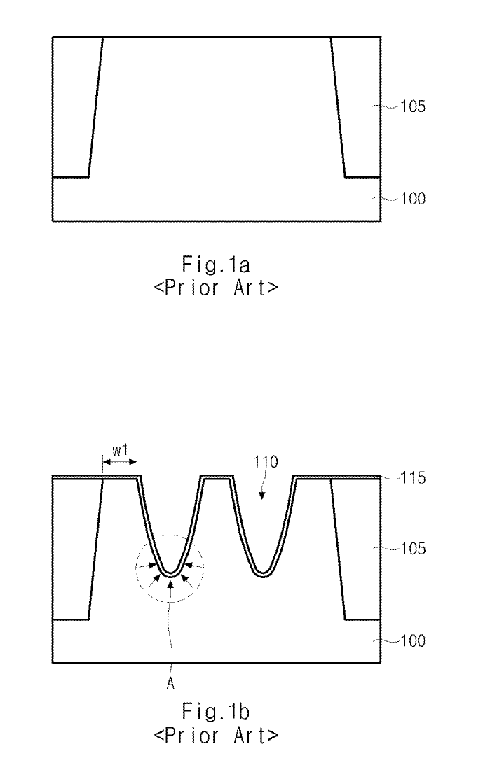

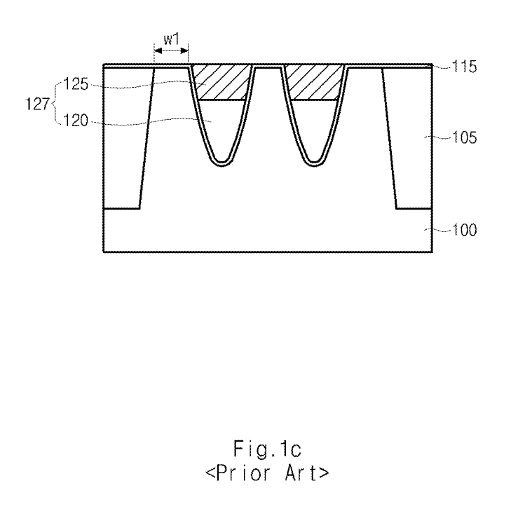

A gate hard mask 240 is formed on the top portion of the gate electrode material 235, thereby obtaining a buried gate 242. The buried gate 242 includes an upper gate pattern with a first width, and a lower gate pattern with a second width. The second width is larger than the first width. The lower gate pattern is enlarged in a direction along the surface of the substrate 200. Comparing FIG. 2j with FIG. 1c, a distance W2 between the device isolation film 205 and the upper gate pattern of the buried gate 242 shown in FIG. 2j is longer than a distance w1 between the device isolation film 105 and an upper portion of the buried gate 127 shown in FIG. 1c. The larger contact area for a bit line pattern or a storage node pattern can be ensured. The bit line pattern and the storage node pattern are formed over the silicon layer 225 so as to be electrically coupled to a gate junction (a source/drain region) formed in or over the silicon layer 225. As the silicon layer 225 can be ensured in a large size, contact resistance between the gate junction and the bit line pattern or between the gate junction and the storage node pattern can be improved.

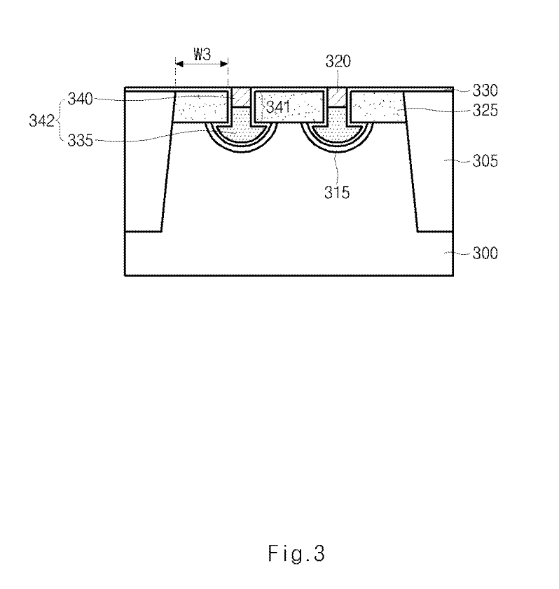

FIG. 3 is a cross-sectional diagram illustrating a semiconductor device according to an embodiment of the present invention.

Referring to FIG. 3, a buried gate 342 is disposed in a semiconductor substrate 300 including a device isolation film 305.

The buried gate 342 includes a recess that has a lower portion having a half-circular shape with a large radius of curvature, and a neck part 341 over the lower portion having a smaller width than that of the lower portion. A gate electrode material 335 is buried in the lower portion of the buried gate 342, and a gate hard mask 340 is disposed on the top portion of the gate electrode material 335. The gate hard mask 340 is formed with a substantially uniform thickness between the semiconductor substrate 300 and the gate electrode material 335 in the lower portion of the recess.

A first gate insulating film 315 is disposed in the lower portion of the buried gate 342 with a substantially uniform thickness. The first gate insulating film 315 is formed with a material including an oxide film. A second gate insulating film 330 may be further formed over the first gate insulating film 315 in order to supplement the first gate insulating film 315 which may have been damaged at preceding steps. The process for forming a second gate insulating film 330 may not be performed.

Since the lower portion of the buried gate 342 is formed to have an enlarged width, for example, in a half-circular shape with a large radius of curvature, the gate insulating film 315 having a uniform thickness may be formed by a thermal oxidation process. A distance W3 between the device isolation film 305 and an upper portion of the buried gate 342 is long in comparison with the prior art, thereby increasing the contact area for connecting between a gate junction in or on the silicon layer 325 and a bit line or a storage node pattern each of which will be formed in a subsequent process. As a result, contact resistance can be improved.

As described above, the embodiments of the present invention can improve a DIBL characteristic with a large radius of curvature, thereby improving a gate characteristic. Also, an area of a region for connecting a gate junction increases to improve contact resistance.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for fabricating a semiconductor device, the method comprising:
forming a mask pattern over a semiconductor substrate including a device isolation film;
etching the semiconductor substrate with the mask pattern as a barrier to form a recess having a semi-circular shape;
filling a sacrificial material in the semi-circular shaped recess and between the mask pattern;
removing the mask pattern;
forming a silicon layer in a portion where the mask pattern is removed;
removing the sacrificial material to form a gate region; and
providing gate electrode material in the gate region to form a gate pattern.

2. The method according to claim 1, wherein the device isolation film is formed at a higher level than the top surface of the semiconductor substrate.

3. The method according to claim 1, wherein the width of the top side of the recess is formed to be larger than that between the mask patterns.

4. The method according to claim 1, wherein the width between the mask patterns ranges reduced by 20 to 50% to with respect to the size of a buried gate.

5. The method according to claim 1, wherein the forming-a-mask-pattern includes:
performing a photo-etching process with a buried gate mask to form a pattern; and
forming a spacer at sidewalls of the pattern.

6. The method according to claim 1, wherein the forming-a-recess is performed by an isotropic process,
wherein the semi-circular shape has a width that is greater than the depth.

7. The method according to claim 1, after forming a recess, further comprising forming a gate insulating film on the surface of the recess.

8. The method according to claim 1, wherein the sacrificial material includes one selected from the group consisting of a nitride film, an oxide film and a combination thereof.

9. The method according to claim 1, wherein the forming-a-silicon-layer includes depositing silicon in the portion where the mask pattern is removed.

10. The method according to claim 1, wherein the forming-a-silicon-layer is performed by a Selective Epitaxial Growth (SEG) process.

11. The method according to claim 1, wherein the silicon layer is formed to a higher location than that of the sacrificial material.

12. The method according to claim 1, after forming a silicon layer, further comprising depositing a gate insulating film.

13. A semiconductor device comprising:
a gate region including a recess in a semiconductor substrate and a neck part having a smaller width than that of the recess, the recess having a width and a depth, the width of the recess being greater than the depth of the recess;
a gate electrode formed in a lower portion of the gate region; and
a gate hard mask disposed on an upper portion of the gate electrode.

14. The semiconductor device according to claim 13, further comprising a gate insulating film disposed below the gate electrode.

15. The semiconductor device according to claim 13, further comprising a silicon layer disposed at a side of the neck part of the gate region.

16. The semiconductor device according to claim 13, wherein the gate electrode is formed in the recess and a lower portion of the neck part.

17. A semiconductor device comprising:
a buried gate pattern formed in a substrate, the buried gate including a lower gate pattern formed in a recess and an upper gate pattern extending from the lower gate pattern,
wherein the upper gate pattern has a first width, and the lower gate pattern has a second width larger than the first width.

18. The semiconductor device according to claim 17, wherein the substrate comprising:
a first substrate formed between the lower gate patterns; and
a second substrate extending from the first substrate and formed between the upper gate patterns.

19. The semiconductor device according to claim 18, wherein the second substrate is an epitaxial layer of the first substrate.

20. The semiconductor device according to claim 18, wherein the recess has a horizontal dimension that is great than a vertical dimension.
